(19) United States
(12) Patent Application Publication
(10) Pub. No.: US 2026/0059730 A1
(43) Pub. Date: Feb. 26, 2026

(54) WIRELESS COMMUNICATION DEVICE

(71) Applicant: SONY GROUP CORPORATION, Tokyo (JP)

(72) Inventor: Kouji ENDOU, Tokyo (JP)

(21) Appl. No.: 19/102,847

(22) PCT Filed: Jul. 31, 2023
(86) PCT No.: PCT/JP2023/027930

§ 371 Date: Feb. 10, 2025

(30) Foreign Application Priority Data
Aug. 18, 2022 (JP) 2022-130741

(51) Int. Cl. H05K 9/00; H01Q 1/22; H01Q 1/52; H04B 1/40; H05K 7/14

(52) U.S. Cl. CPC H05K 9/0081; H01Q 1/22; H01Q 1/526; H04B 1/40; H05K 7/1427

(57) ABSTRACT

A wireless communication device of the present disclosure includes a substrate, a housing, a wireless communication circuit, and a shield case. At least a part of a top surface of the housing is opened, the top surface facing a second surface of the substrate opposite to a first surface on which a terminal is formed. The wireless communication circuit is disposed on the second surface. The shield case has a third surface having substantially the same height as that of a surface where an opening of the top surface is formed and shields the wireless communication circuit.

### FIELD

The present disclosure relates to a wireless communication device.

### BACKGROUND

There is known technology of imparting a communication function to a card-type device by mounting a communication circuit on a thin card-type device (for example, Patent Literature 1). In a case where a card-type device has a communication function, a communication circuit is covered with a shield.

### CITATION LIST

### Patent Literature

Patent Literature 1: JP 2011-154642 A

### SUMMARY

### Technical Problem

There are cases where, in card-type devices, the size including the thickness is defined in advance by standards or the like, such as the SD cards. In addition, even in a card-type device whose size is not set, it is desirable that the device be molded as thin as possible.

Meanwhile, as described above, in a case where a thin device such as a card-type device has a communication function, a communication circuit, a shield, and the like are additionally mounted on the device. Therefore, since the number of components mounted on the thin device increases, the size, particularly the thickness, of the device may increase in order to secure a space for mounting the components.

Therefore, the present disclosure provides a wireless communication device capable of suppressing an increase in the thickness.

Note that the above disadvantage or object is merely one of a plurality of disadvantages or objects that can be solved or achieved by a plurality of embodiments disclosed herein.

### Solution to Problem

A wireless communication device of the present disclosure includes a substrate, a housing, a wireless communication circuit, and a shield case. At least a part of a top surface of the housing is opened, the top surface facing a second surface of the substrate opposite to a first surface on which a terminal is formed. The wireless communication circuit is disposed on the second surface. The shield case has a third surface having substantially the same height as that of a surface where an opening of the top surface is formed and shields the wireless communication circuit.

### BRIEF DESCRIPTION OF DRAWINGS

FIG. 1 is a cross-sectional view illustrating an example of a schematic configuration of a wireless communication device according to a first embodiment of the present disclosure.

FIG. 2 is a cross-sectional view illustrating an example of a schematic configuration of a card-type device.

FIG. 3 is a diagram for explaining the thickness of the wireless communication device according to the first embodiment of the present disclosure.

FIG. 4 is a cross-sectional view illustrating an example of a schematic configuration of a wireless communication device according to a second embodiment of the present disclosure.

FIG. 5 is a top view illustrating an example of a schematic configuration of the wireless communication device according to the second embodiment of the present disclosure.

FIG. 6 is a bottom view illustrating an example of a schematic configuration of the wireless communication device according to the second embodiment of the present disclosure.

FIG. 7 is an exploded perspective view illustrating an example of a schematic configuration of the wireless communication device according to the second embodiment of the present disclosure.

FIG. 8 is a diagram for explaining an example of an application region of an adhesive according to the second embodiment of the present disclosure.

FIG. 9 is a cross-sectional view illustrating an example of a schematic configuration of a wireless communication device according to a modification of the second embodiment of the present disclosure.

### DESCRIPTION OF EMBODIMENTS

Hereinafter, embodiments of the disclosure will be described in detail by referring to the accompanying drawings. Note that, in the present specification and the drawings, components that are substantially the same are denoted by the same symbols, and redundant description is omitted.

One or a plurality of embodiments (including examples and modifications) described below can be each implemented independently. Meanwhile, at least a part of the plurality of embodiments described below may be combined with and implemented together with at least a part of another embodiment as appropriate. The plurality of embodiments may include novel features different from each other. Therefore, the plurality of embodiments can contribute to solving mutually different objects or disadvantages or achieve mutually different effects.

### 1. First Embodiment

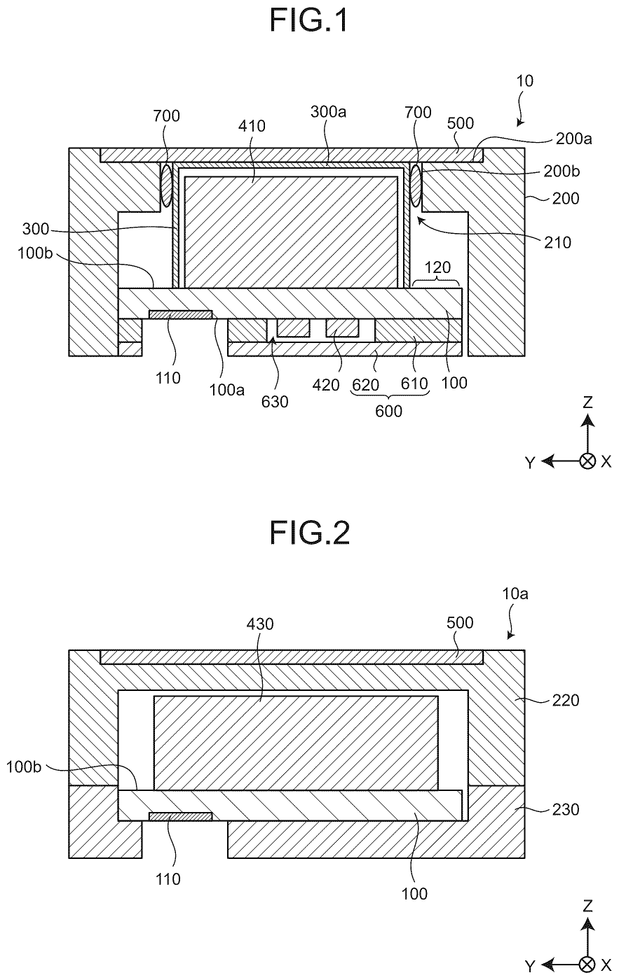

FIG. 1 is a cross-sectional view illustrating an example of a schematic configuration of a wireless communication device 10 according to a first embodiment of the present disclosure. In the present embodiment, a case where a thin device (wireless communication device 10) having a wireless communication function is an SD card or a multimedia card will be described as an example; however, the wireless communication device 10 is not limited thereto. The wireless communication device 10 may be, for example, a card-type device or the like and may be a memory stick, a USB memory, or the like.

Note that, in each of the following drawings, an X-axis direction, a Y-axis direction, and a Z-axis direction orthogonal to each other are defined to facilitate understanding of the description. In this orthogonal coordinate system, an XY plane is parallel to a plane of the wireless communication device 10. The Y-axis positive direction is a direction in which the wireless communication device 10, which is an SD card, is inserted into a slot. The Z-axis positive direction is a vertically upward direction with respect to the direction in which the wireless communication device 10 is inserted into the slot. The X-axis direction is orthogonal to the Y-axis and the Z-axis.

The wireless communication device 10 illustrated in FIG. 1 includes a substrate 100, a housing 200, a shield case 300, a wireless communication circuit 410, circuits 420, a front sheet 500, and a back sheet 600.

The substrate 100 is formed of, for example, a resin such as glass fiber reinforced epoxy resin, a copper pattern, and others. A terminal (contact terminal) 110 is provided in an end region of a back surface 100a (an example of a first surface) of the substrate 100. The terminal 110 is used for communication with an external device (not illustrated) into which the wireless communication device 10 is inserted.

An end region 120 of the substrate 100 on the opposite side to the end region where the terminal 110 is provided is an antenna region (hereinafter, also referred to as an antenna region 120) where an antenna (not illustrated) is formed. The antenna is formed, for example, on a front surface 100b (an example of a second surface) of the substrate 100 as a part of a wiring pattern.

The housing 200 is formed of, for example, a thermoplastic resin such as polycarbonate or acrylonitrile butadiene styrene (ABS). Note that the material of the housing 200 is not limited to the thermoplastic resins.

The housing 200 has an opening in a bottom surface and a part of an upper surface. The opening included in the upper surface of the housing 200 is also referred to as an opening 210. In addition, on the upper surface of the housing 200, a recess is included in order to prevent the front sheet 500 from protruding when the front sheet 500 is attached, namely, in order to make a step hardly generated between the front sheet 500 and the upper surface of the housing 200. The flat portion of the recess is also referred to as a top surface 200a so as to be distinguished from the upper surface. The top surface 200a is a surface on which the opening 210 is formed.

The wireless communication circuit 410 is disposed, for example, on the front surface 100b side of the substrate 100. The wireless communication circuit 410 is disposed such that, for example, a part thereof is located in the opening 210 of the housing 200.

The wireless communication circuit 410 performs wireless communication with another wireless communication device (not illustrated) via an antenna (not illustrated), for example, in a state where the wireless communication device 10 is inserted in an SD card slot. The wireless communication circuit 410 performs wireless communication on the basis of, for example, long term evolution (LTE). Note that the communication method adopted by the wireless communication circuit 410 is not limited to LTE. The wireless communication circuit 410 may perform wireless communication with another mobile communication system such as the fifth generation mobile communications system (5G). Alternatively, the wireless communication circuit 410 may perform wireless communication in accordance with a wireless communication scheme such as Wi-Fi (registered trademark) or Bluetooth (registered trademark) in addition to the mobile communication system.

The circuits 420 are disposed, for example, on the back surface 100a side of the substrate 100.

The shield case 300 suppresses electrical interference between the wireless communication circuit 410 and the antenna. The shield case 300 is formed of metal such as stainless steel. The shield case 300 is disposed on the front surface 100b side of the substrate 100 in such a manner as to cover the wireless communication circuit 410.

As illustrated in FIG. 1, the shield case 300 has an upper surface 300a (an example of a third surface) at substantially the same height as that of the top surface 200a of the housing 200. That is, the distance from the substrate 100 to the upper surface 300a is substantially the same as the distance from the substrate 100 to the opening 210 (or the top surface 200a). Furthermore, side surfaces of the shield case 300 are bonded to side surfaces 200b of the opening 210 of the housing 200 by an adhesive 700.

The front sheet 500 (an example of a sheet) is, for example, a label of the SD card. The front sheet 500 is bonded to the top surface 200a of the housing 200 and the upper surface 300a of the shield case 300 in such a manner as to close the opening 210 of the housing 200.

The back sheet 600 (an example of a second sheet) is attached to the back surface 100a of the substrate 100 in such a manner as to cover the circuits 420. The back sheet 600 includes a first sheet 610 and a second sheet 620. The first sheet 610 is attached to the back surface 100a of the substrate 100. The first sheet 610 has an opening 630 in at least a part thereof. The circuits 420 described above are arranged in the opening 630 of the first sheet 610.

The second sheet 620 is attached to the first sheet 610 in such a manner as to close the opening 630 of the first sheet 610.

With the back sheet 600 attached to the back surface 100a of the substrate 100, the bottom surface (back surface) of the wireless communication device 10 is closed by the back sheet 600.

Note that it is desirable that the opening 630 is not included in a region of the first sheet 610 corresponding to the antenna region 120 of the substrate 100. That is, it is desirable that the circuits 420 be arranged in a region of the substrate 100 excluding the antenna region 120. This is to suppress electrical interference between the circuits 420 and the antenna.

The back sheet 600 is attached to the back surface 100a of the substrate 100 such that the terminal 110 disposed on the back surface 100a of the substrate 100 is exposed.

As described above, the wireless communication device 10 according to the present embodiment includes the substrate 100, the housing 200, the wireless communication circuit 410, and the shield case 300. In the housing 200, at least a part of the top surface 200a is opened, the top surface 200a facing the front surface 100b opposite to the back surface 100a on which the terminal 110 is formed. The wireless communication circuit 410 is disposed on the front surface 100b of the substrate 100. The shield case 300 has the upper surface 300a having substantially the same height as that of the top surface 200a of the housing 200 and shields the wireless communication circuit 410.

As a result, in the wireless communication device 10, it is possible to suppress an increase in the thickness of the housing 200. For example, even in a case where the wireless communication device 10 has the shield case 300 and the circuits 420 arranged on the back surface 100a of the substrate 100, the housing 200 can be thinned and prevented from being thick.

Note that, although FIG. 1 illustrates an example in which the wireless communication circuit 410 is disposed in the shield case 300, the circuit arranged in the shield case 300 is not limited to the wireless communication circuit 410. For example, a memory circuit (storage medium), an arithmetic circuit, and the like may be disposed in the shield case 300.

Furthermore, in FIG. 1, no circuits are arranged outside the shield case 300 on the front surface 100b of the substrate 100; however, a circuit (for example, a memory circuit, an arithmetic circuit, or the like) may be disposed outside the shield case 300.

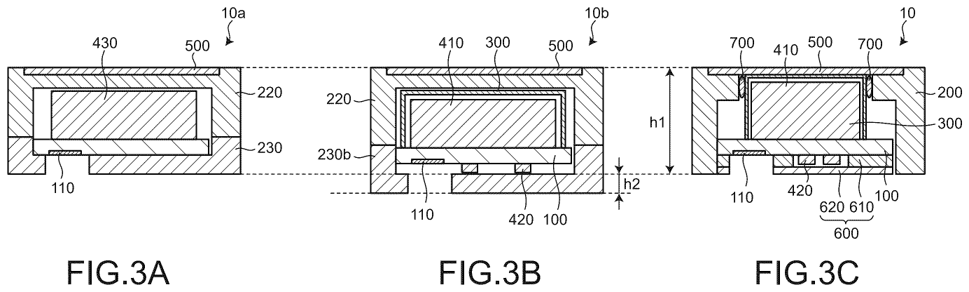

Next, the reason why an increase in the thickness of the housing 200 can be suppressed will be described with reference to FIGS. 2 and 3.

FIG. 2 is a cross-sectional view illustrating an example of a schematic configuration of a card-type device 10a. The card-type device 10a illustrated in FIG. 2 is, for example, an SD card. Note that the same components as those in FIG. 1 are denoted by the same symbols, and description thereof is omitted.

As illustrated in FIG. 2, the card-type device 10a includes a substrate 100, a first cabinet 220, a second cabinet 230, a circuit 430, and a front sheet 500.

The circuit 430 is disposed on a front surface 100b of the substrate 100. The circuit 430 is, for example, a memory circuit or the like.

The first cabinet 220 and the second cabinet 230 function as a housing of the card-type device 10a. Bonding is performed with the inner surface of the first cabinet 220 and the inner surface of the second cabinet 230 facing each other. The substrate 100 and the circuit 430 are accommodated in an internal space of the housing thus formed. The second cabinet includes an opening such that a terminal 110 is exposed therefrom.

A wireless communication function is added by mounting a wireless communication circuit 410 and an antenna on the card-type device 10a formed in this manner. In this case, in addition to the wireless communication circuit 410 and the antenna, a shield case 300 for suppressing electrical interference therebetween is mounted on the card-type device 10a.

When the number of components mounted on the card-type device 10a increases, the card-type device 10a becomes large in size. This point will be described by referring to FIG. 3.

FIG. 3 is a diagram for explaining the thickness of the wireless communication device 10 according to the first embodiment of the present disclosure. In FIG. 3, some symbols are omitted in order to enhance the visibility of the drawing.

In FIG. 3(a), the card-type device 10a illustrated in FIG. 2 is illustrated. Illustrated in FIG. 3(b) is a wireless communication device 10b obtained by amounting the wireless communication function on the card-type device 10a. Illustrated in FIG. 3(c) is the wireless communication device 10 according to the first embodiment of the present disclosure.

The wireless communication device 10b illustrated in FIG. 3(b) is different from the card-type device 10a in that a wireless communication circuit 410 is included instead of the circuit 430. The wireless communication device 10b further includes a shield case 300 and circuits 420. The circuits 420 may be, for example, circuits that cannot be arranged on a front surface 100b of a substrate 100 due to mounting of the wireless communication circuit 410. The circuits 420 are arranged on a back surface 100a of the substrate 100.

As illustrated in FIG. 3(b), the thickness (height) of the wireless communication device 10b is thicker than that of the card-type device 10a illustrated in FIG. 3(a) by h2 due to the shield case 300 and the circuits 420 arranged on the back surface 100a. For example, in a case where the thickness of the card-type device 10a is h1, the thickness of the wireless communication device 10b is h1+h2.

In this case, in a case where the card-type device 10a and the wireless communication device 10b are SD cards, the size thereof including the thickness is defined by standards. Therefore, the wireless communication device 10b may not be able to satisfy the standards since the thickness is increased by the shield case 300 and the circuits 420 arranged on the back surface 100a.

Therefore, as illustrated in FIG. 3(c), the wireless communication device 10 according to the present embodiment includes the opening 210 on the upper surface of the housing 200. The wireless communication device 10 also has an opening on the bottom surface of the housing 200.

In the wireless communication device 10, the shield case 300 and a part of the wireless communication circuit 410 are arranged in the opening 210 on the upper surface. As a result, in the wireless communication device 10, it is possible to suppress an increase in the thickness of the wireless communication device 10 due to the shield case 300 or the circuits 420 provided therein.

In addition, in the wireless communication device 10, the back sheet 600 is provided in the opening of the bottom surface of the housing 200, and the circuits 420 are arranged in the opening 630 of the back sheet 600. As a result, in the wireless communication device 10, it is possible to suppress an increase in the thickness of the wireless communication device 10 due to the shield case 300 or the circuits 420 provided therein.

As described above, the wireless communication device 10 according to the present embodiment is less likely to be thick due to an increase in the number of components, whereby the height (thickness) can be suppressed to the height hl similarly to the card-type device 10a of FIG. 3(a). As a result, the wireless communication device 10 according to the present embodiment can be thinned while having a wireless communication function and can satisfy standards for, for example, the SD cards.

In addition, in the wireless communication device 10, at least a part of the shield case 300 is disposed in the opening 210 of the housing 200. The upper surface 300a of shield case 300 is disposed at substantially the same height as that of the top surface 200a of the housing 200. The shield case 300 is made of metal as mentioned above. As a result, even though the opening 210 is formed in the housing 200, the wireless communication device 10 can maintain its strength.

In addition, the housing 200 and the shield case 300 are bonded to each other by the adhesive 700. As a result, for example, even in a case where a twisting force is applied to the wireless communication device 10, damage to the wireless communication device 10 can be further suppressed.

In this manner, the wireless communication device 10 can increase its strength while enabling more circuits to be mounted thereon.

### 2. Second Embodiment

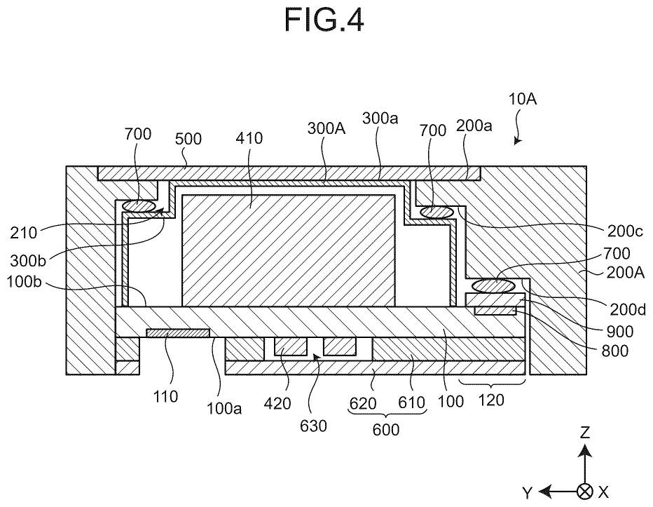

FIG. 4 is a cross-sectional view illustrating an example of a schematic configuration of a wireless communication device 10A according to a second embodiment of the present disclosure. The wireless communication device 10A illustrated in FIG. 4 further includes an antenna 800 and an antenna sheet 900 in addition to the configuration of the wireless communication device 10 illustrated in FIG. 1. Note that the wireless communication device 10A is different from the wireless communication device 10 illustrated in FIG. 1 in the shape of a housing 200A and the shape of a shield case 300A.

As illustrated in FIG. 4, the shield case 300A has a stepped surface 300b (an example of a fourth surface) lower than an upper surface 300a (an example of a third surface). The shield case 300A and the housing 200A are bonded to each other by an adhesive 700 at least at a part of the stepped surface 300b.

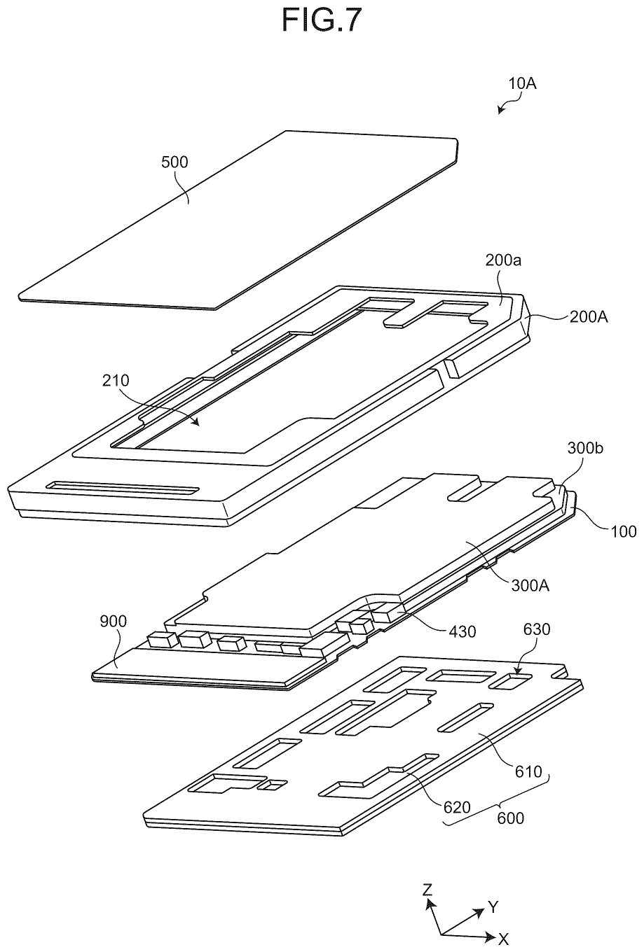

As described above, the shield case 300A has a stepped shape. The stepped surface 300b constituting the stepped shape is formed, for example, on at least a part of the outer periphery of the shield case 300A (see FIG. 7 described later).

In addition, the wireless communication device 10A includes the antenna 800 as pattern wiring on a substrate 100. The wireless communication circuit 410 of the wireless communication device 10A performs wireless communication with another wireless communication device (not illustrated) via the antenna 800.

In the example of FIG. 4, the antenna sheet 900 is disposed on the antenna 800 and on a front surface 100b of the substrate 100. The antenna sheet 900 may have a function of protecting the antenna 800. The antenna sheet 900 is bonded to the housing 200A by an adhesive 700. Accordingly, the housing 200A and the substrate 100 are bonded to each other.

The housing 200A has a stepped shape inside the housing 200A. For example, the housing 200A has a first bonding surface 200c and a second bonding surface 200d.

The first bonding surface 200c is, for example, a surface located on the opposite side of a top surface 200a to which a front sheet 500 is bonded. The first bonding surface 200c is formed at a position facing the stepped surface 300b of the shield case 300A. The housing 200A is bonded to the stepped surface 300b of the shield case 300A via the adhesive 700 on the first bonding surface 200c.

The second bonding surface 200d is, for example, a surface located on the opposite side of the upper surface of the housing 200A and in an antenna region 120 of the substrate 100. The second bonding surface 200d is formed at a position facing the antenna sheet 900. The housing 200A is bonded to the antenna sheet 900 via the adhesive 700 on the second bonding surface 200d.

As described above, the shield case 300A of the wireless communication device 10A according to the present embodiment has a stepped shape. As a result, in the wireless communication device 10A, it is possible to further expand the internal space of the shield case 300A. Therefore, the wireless communication device 10A allows more circuits to be arranged in the shield case 300A as compared with the first embodiment.

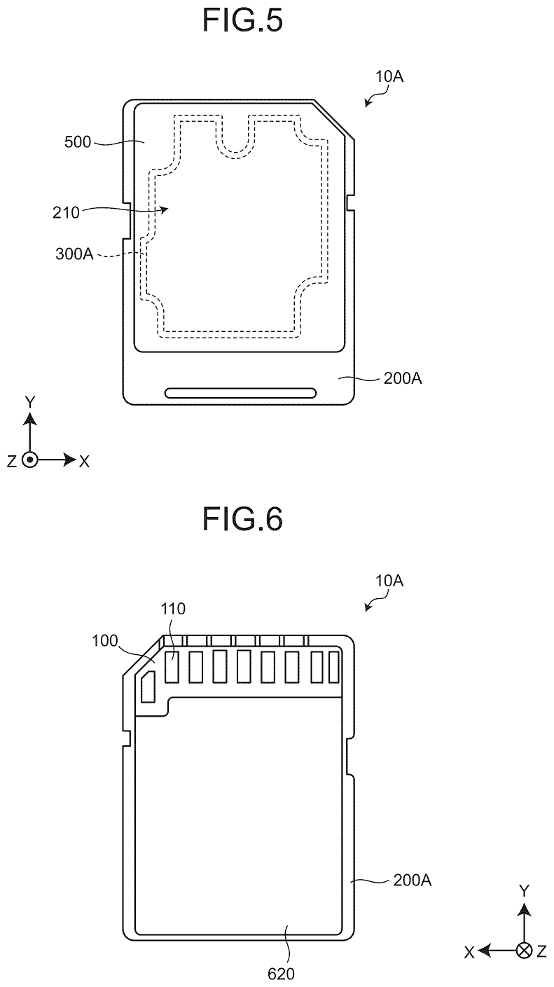

FIG. 5 is a top view illustrating an example of a schematic configuration of the wireless communication device 10A according to the second embodiment of the present disclosure. FIG. 6 is a bottom view illustrating an example of a schematic configuration of the wireless communication device 10A according to the second embodiment of the disclosure.

FIG. 5 is a diagram illustrating the wireless communication device 10A as viewed from above (Z-axis positive direction). As illustrated in FIG. 5, the opening 210 of the housing 200A has a shape having a plurality of concave portions and protruding portions. The shape of the opening 210 can vary such as a quadrangular shape, a circular shape, or a polygonal shape. The opening 210 has a shape corresponding to the shape of the upper surface 300a of the shield case 300A, namely, the number, the shape, or the size of circuits (for example, the wireless communication circuit 410) mounted in the shield case 300A, the arrangement of the circuits, and others.

The front sheet 500 is attached to the housing 200A and the shield case 300A in such a manner as to cover the opening 210. In this manner, with the housing 200A and the shield case 300A fixed also by the front sheet 500, the strength of the wireless communication device 10A is enhanced.

FIG. 6 is a diagram illustrating the wireless communication device 10A as viewed from below (Z-axis negative direction). As illustrated in FIG. 6, the second sheet 620 of the back sheet 600 is attached to the substrate 100 such that terminals 110 of the substrate 100 are exposed.

Attaching the back sheet 600 to the substrate 100 in this manner eliminates the need to cover the back surface side of the wireless communication device 10A with the second cabinet 230 (see FIG. 2). This allows circuits to be mounted on the back surface 100a of the substrate 100, whereby more circuits can be mounted on the wireless communication device 10A.

FIG. 7 is an exploded perspective view illustrating an example of a schematic configuration of the wireless communication device 10A according to the second embodiment of the present disclosure.

As illustrated in FIG. 7, the shield case 300A has a stepped shape on at least a part of the outer peripheral portion. In this manner, the stepped surface 300b may not be provided on the entire outer peripheral portion of the shield case 300A. The shape of the shield case 300A has a shape corresponding to the number, the shape, or the size of circuits (for example, the wireless communication circuit 410) mounted inside, the arrangement of the circuits, and others.

As illustrated in FIG. 7, a circuit 430 is also disposed on the substrate 100 outside the shield case 300A. The shape of the shield case 300A is determined depending on the number, the shape, or the size of the circuits 430, the arrangement of the circuits 430, and others.

A plurality of openings 630 is formed in the back sheet 600. The number or the shape of the openings 630 are determined depending on the shape number, the shape, or the size of circuits 420 arranged on the back surface 100a of the substrate 100, the arrangement of the circuits, and others.

In the example described above, the housing 200A and the shield case 300 are bonded to each other by the adhesive 700 on the first bonding surface 200c of the housing 200A and the stepped surface 300b of the shield case 300A; however, the position where the adhesive 700 is applied is not limited thereto.

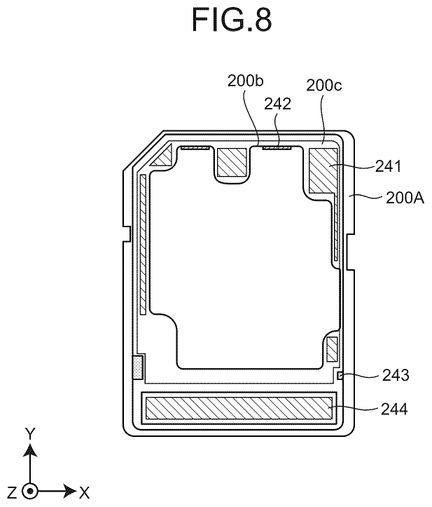

FIG. 8 is a diagram for explaining an example of an application region of the adhesive 700 according to the second embodiment of the present disclosure.

As illustrated in FIG. 8, the adhesive 700 is applied to a first application region 241 which is at least a part of the first bonding surface 200c of the housing 200A. In addition, the adhesive 700 is applied to a second application region 242 which is at least a part of a side surface 200b of the housing 200A. The housing 200A and the shield case 300A are bonded to each other by the adhesive 700 applied to the first application region 241 and the second application region 242.

As illustrated in FIG. 8, the adhesive 700 is applied to a third application region 243 on a lower side (Y-axis negative direction) of the housing 200A. The housing 200A and the substrate 100 are bonded by the adhesive 700 applied to the third application region 243.

Furthermore, as illustrated in FIG. 8, the adhesive 700 is applied to a fourth application region 244 on a lower side (Y-axis negative direction) of the housing 200A. The fourth application region 244 corresponds to the antenna region 120 of the substrate 100. The housing 200A and the antenna sheet 900 are bonded to each other by the adhesive 700 applied to the fourth application region 244.

As described above, the antenna sheet 900 is attached to the antenna region 120 of the substrate 100. Therefore, the housing 200A and the substrate 100 are bonded to each other by the adhesive 700 applied to the fourth application region 244 and the antenna sheet 900.

Note that the application regions illustrated in FIG. 8 are an example, and the adhesive 700 may be applied to other regions, and the adhesive 700 may not be applied to the application regions illustrated in FIG. 8. It is only required that the adhesive 700 be applied to bond the housing 200A and the shield case 300A and to bond the housing 200A and the substrate 100. The application region of the adhesive 700 may be modified as appropriate depending on the size of the housing 200A, the shape of the shield case 300A, circuits arranged on the substrate 100, or others.

### 3. Modification

In the second embodiment described above, the case where the corner portion of the shield case 300A is at a right angle has been described; however, the shape of the shield case 300A is not limited thereto.

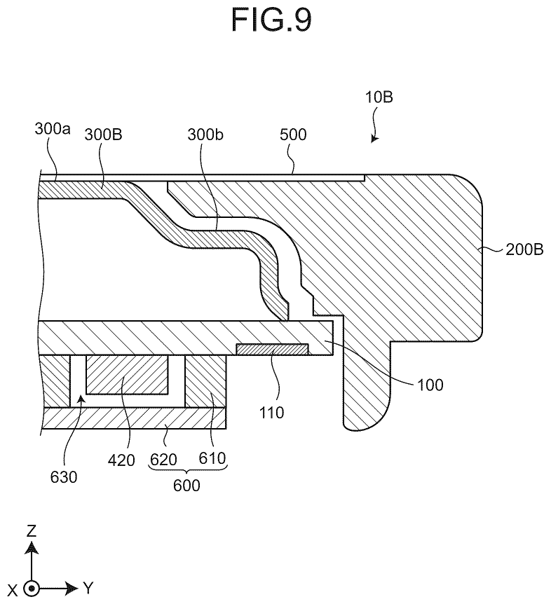

FIG. 9 is a cross-sectional view illustrating an example of a schematic configuration of a wireless communication device 10B according to a modification of the second embodiment of the present disclosure.

In the wireless communication device 10B illustrated in FIG. 9, the shapes of a housing 200B and a shield case 300B are different from those of the wireless communication device 10A illustrated in FIG. 4.

For example, in the shield case 300B, a surface connecting an upper surface 300a and a stepped surface 300b is inclined with respect to the upper surface 300a and the stepped surface 300b.

In this manner, each surface of the shield case 300B may not be, for example, orthogonal to or parallel to a substrate 100 and may be formed obliquely with respect to the substrate 100. In FIG. 9, the stepped surface 300b facing a first bonding surface 200c of the housing 200B is formed in such a manner as to be parallel to the substrate 100; however, the stepped surface 300b may also be formed obliquely with respect to the substrate 100.

Furthermore, the corner portion of the shield case 300B has a curved shape with rounded corners. Furthermore, an end (a side in contact with the substrate 100) of the shield case 300B has a shape curved outward. As described above, the corner portion or the end of the shield case 300B may be formed in a curved surface shape.

The housing 200B has a shape corresponding to the shape of the shield case 300B. For example, the housing 200B is formed such that the inner surface faces the side surface (surface excluding the upper surface 300a) of the shield case 300B with a predetermined gap therebetween.

As described above, since the housing 200B has a shape corresponding to the shape of the shield case 300B, the shield case 300B and the housing 200B are firmly bonded to each other by the adhesive 700 (not illustrated in FIG. 9). As a result, the strength of the wireless communication device 10B can be further enhanced.

In the second embodiment, the case where the number of steps of the shield case 300A is one, that is, there is a single stepped surface 300b has been described; however, the number of steps of the shield case 300A may be two or more. That is, a plurality of stepped surfaces 300b having different heights may be formed in the shield case 300A.

Furthermore, in this example, the modification of the wireless communication device 10A according to the second embodiment has been described; however, the wireless communication device 10 according to the first embodiment may also be modified in a similar manner.

As described above, the wireless communication devices 10, 10A, and 10B according to the technology of the present disclosure are formed such that the shield cases 300, 300A, and 300B are positioned in at least a part of the openings 210 of the housings 200, 200A, and 200B, respectively. Meanwhile, the shapes of the housings 200, 200A, and 200B, the shield cases 300, 300A, and 300B, and the like may by any shape.

### 4. Summary

Although the embodiments of the disclosure have been described above, the technical scope of the disclosure is not limited to the above embodiments as they are, and various modifications can be made without departing from the gist of the disclosure. In addition, components of different embodiments and modifications may be combined as appropriate.

For example, the technology of the present disclosure is not necessarily limited to a thin type such as a card type and may be applied to one having a three-dimensional shape. For example, despite a three-dimensional shape, the technology of the present disclosure is applicable in a case where the thickness (the length in the Z-axis direction) is restricted.

Furthermore, the effects of the embodiments described herein are merely examples and are not limiting, and other effects may be achieved.

Note that the present technology can also have the following configurations.
(1)

A wireless communication device comprising:
a substrate;
a housing in which at least a part of a top surface is opened, the top surface facing a second surface of the substrate opposite to a first surface on which a terminal is formed;
a wireless communication circuit disposed on the second surface; and
a shield case that shields the wireless communication circuit, the shield case having a third surface having substantially the same height as a height of a surface where an opening of the top surface is formed.
(2)

The wireless communication device according to (1), wherein
the shield case has a fourth surface lower than the third surface, and
the shield case and the housing are bonded to each other by an adhesive on at least a part of the fourth surface.
(3)

The wireless communication device according to (1) or (2), further comprising a sheet attached to the top surface of the housing and the third surface of the shield case.
(4)

The wireless communication device according to any one of (1) to (3), further comprising an antenna for the wireless communication circuit to perform communication.
(5)

The wireless communication device according to (4), wherein the antenna is provided in an end region of the substrate on an opposite side to a region of the substrate where the terminal is provided.
(6)

The wireless communication device according to any one of (1) to (5), further comprising a circuit disposed on the first surface of the substrate.
(7)

The wireless communication device according to (6), further comprising
an antenna with which the wireless communication circuit performs communication, the antenna disposed on the substrate, wherein
the circuit is disposed on the first surface of the substrate on which the antenna is not disposed.
(8)

The wireless communication device according to (6) or (7), further comprising a second sheet attached to the first surface of the substrate and covering the circuit.
(9)

The wireless communication device according to any one of (1) to (8), further comprising a storage medium disposed on the substrate.
(10)

The wireless communication device according to any one of (1) to (9), wherein the wireless communication circuit performs wireless communication in a state where the wireless communication device is inserted in an SD card slot.

### REFERENCE SIGNS LIST

10, 10A, 10B WIRELESS COMMUNICATION DEVICE
100 SUBSTRATE
110 TERMINAL
200, 200A, 200B HOUSING
300, 300A, 300B SHIELD CASE
410 WIRELESS COMMUNICATION CIRCUIT
420 CIRCUIT
500 FRONT SHEET
600 BACK SHEET
610 FIRST SHEET
620 SECOND SHEET
700 ADHESIVE
800 ANTENNA
900 ANTENNA SHEET

What is claimed is:

1. A wireless communication device comprising:
a substrate;
a housing in which at least a part of a top surface is opened, the top surface facing a second surface of the substrate opposite to a first surface on which a terminal is formed;
a wireless communication circuit disposed on the second surface; and
a shield case that shields the wireless communication circuit, the shield case having a third surface having substantially the same height as a height of a surface where an opening of the top surface is formed.

2. The wireless communication device according to claim 1, wherein
the shield case has a fourth surface lower than the third surface, and
the shield case and the housing are bonded to each other by an adhesive on at least a part of the fourth surface.

3. The wireless communication device according to claim 1, further comprising a sheet attached to the top surface of the housing and the third surface of the shield case.

4. The wireless communication device according to claim 1, further comprising an antenna for the wireless communication circuit to perform communication.

5. The wireless communication device according to claim 4, wherein the antenna is provided in an end region of the substrate on an opposite side to a region of the substrate where is provided.

6. The wireless communication device according to claim 1, further comprising a circuit disposed on the first surface of the substrate.

7. The wireless communication device according to claim 6, further comprising
an antenna with which the wireless communication circuit performs communication, the antenna disposed on the substrate, wherein
the circuit is disposed on the first surface of the substrate on which the antenna is not disposed.

8. The wireless communication device according to claim 6, further comprising a second sheet attached to the first surface of the substrate and covering the circuit.

9. The wireless communication device according to claim 1, further comprising a storage medium disposed on the substrate.

10. The wireless communication device according to claim 1, wherein the wireless communication circuit performs wireless communication in a state where the wireless communication device is inserted in an SD card slot.
